(19) United States
(12) Patent Application Publication
(10) Pub. No.: US 2026/0173310 A1
(43) Pub. Date: Jun. 18, 2026

(54) WATER-COOLING DEVICE CONNECTION STRUCTURE

(71) Applicant: ASIA VITAL COMPONENTS CO., LTD., New Taipei City (TW)

(72) Inventor: Ching-Hang Shen, New Taipei City (TW)

(21) Appl. No.: 18/983,531

(22) Filed: Dec. 17, 2024

(51) Int. Cl. H05K 7/20

(52) U.S. Cl. CPC H05K 7/20272

(57) ABSTRACT

The present invention relates to a water-cooling device connection structure, comprises a water-cooling unit with an inlet and an outlet, at least one connection unit, and a pipe. The connection unit includes a coupling component and a mating component. The coupling component has a fixed base portion with an extended portion having a first channel. The extended portion connects to the inlet or outlet of the water-cooling unit. The mating component has a receiving base portion with a fitting portion. The front of the receiving base portion connects to the rear of the fixed base portion. A second channel within the fitting portion communicates with the first channel. The pipe is inserted into the second channel and combined with the first channel, allowing the pipe to be connected to the water-cooling unit, thereby achieving a connection between the pipe and the water-cooling unit without the need for welding.

### FIELD OF THE INVENTION

This invention relates to a type of connection structure for water-cooling devices, particularly a water-cooling device connection structure that does not require welding and can significantly reduce water leakage issues, the disclosure of which is hereby incorporated by reference in its entirety.

### BACKGROUND OF THE INVENTION

In recent years, water-cooling devices have been widely used for cooling high-power heat sources. Due to their superior cooling efficiency, they have been adopted not only in personal desktop computers but also in industrial computers, server cabinets, transportation vehicles, and lighting equipment. A water-cooling device mainly comprises a water block, pump, and radiator, where these components are connected by pipe.

Most water-cooling devices use one-time welding, tight fittings, or adhesives to bond the water block, pump, radiator, and pipe. However, if welding is not done properly, it is prone to have problem of leakage of the working fluid. Additionally, welding is time-consuming and prone to pollution. The water block, pump, radiator, and pipe are non-reusable after they are welded.

The conventional approach has the following disadvantages:
1. Prone to have problem of leakage of the working fluid;
2. Complicated manufacturing process;
3. Non-reusable after welding.

Thus, finding a way to address these conventional issues has become a focal point of research for inventors and related industry players.

### SUMMARY OF THE INVENTION

Therefore, to effectively resolve the issues mentioned above, the objective of this invention is to provide a connection structure for a water-cooling device in which at least one pipe is connected to the cooling unit through at least one connection unit. The connection structure may significantly reduce the problem of leakage without welding.

Another objective of this invention is to provide a connection structure for a water-cooling device that reduces labor hours, lowers production costs, and minimizes the pollution caused by the manufacturing processes.

To achieve these objectives, the invention provides a water-cooling device connection structure comprising a cooling unit, at least one connection unit, and at least one pipe. The cooling unit has an inlet, an outlet, and a chamber. The chamber connects the inlet and outlet. The connection unit has a coupling component and a mating component that interfaces with the coupling component. The coupling component has a fixed base portion. The front of the fixed base portion is extended outwardly with an extended portion. The extended portion contains a first channel. A leakage proofing portion fits on the external side of the extended portion. The extended portion connects to either the inlet or outlet of the cooling unit via the leakage proofing portion. The mating component has a receiving base portion. The front of the receiving base portion connects to the rear of the coupling component. The rear of the receiving base portion is extended outwardly with a fitting portion. The fitting portion includes a conical second channel. The second channel connects to the first channel. The pipe has a connecting end. The connecting end fits into the second channel of the mating component and combines with the first channel of the extended portion, thereby connecting the pipe to the chamber of the cooling unit.

Through this structure, the invention allows the pipe to be securely installed on the cooling unit via the connection unit by fitting the leakage proofing portion of the connection unit into the inlet or outlet of the cooling unit. Thereby improving upon conventional metal tubes that being attached to the cooling unit only by welding, which easily led to leakage of the working fluid. Furthermore, the coupling and mating components can be repeatedly assembled and disassembled for reuse, thereby significantly reducing production costs and pollution caused by the manufacturing processes.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a perspective view of the connection structure of the water-cooling device according to the invention;

FIG. 2 is a perspective exploded view of the connection structure of the water-cooling device according to the invention;

FIG. 3 is a perspective assembled view of the connection structure of the water-cooling device according to the invention.

### DETAILED DESCRIPTION OF THE PREFERRED EMBODIMENTS

The purpose, structure, and functional features of this invention will be explained according to the preferred embodiments shown in the accompanying drawings.

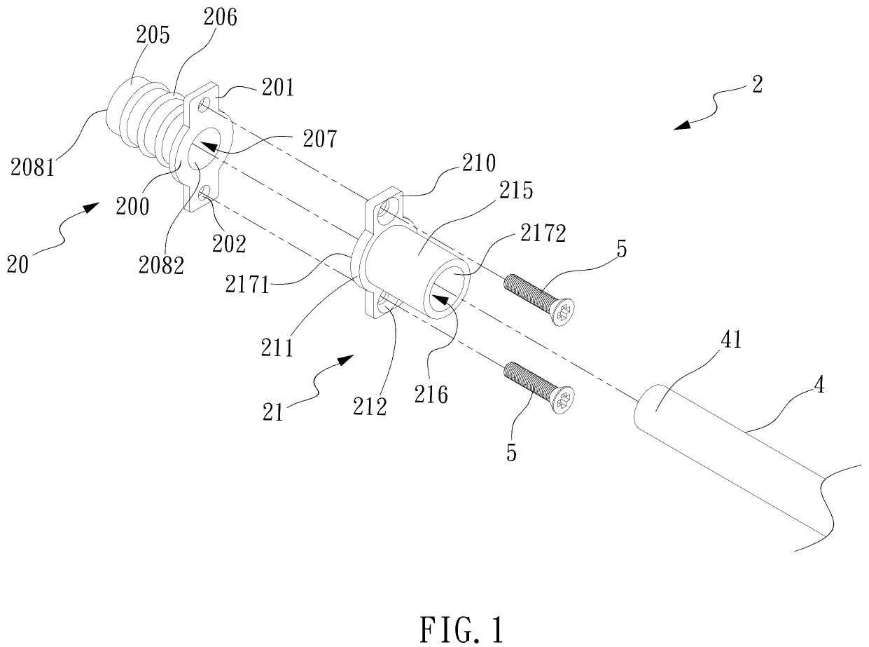

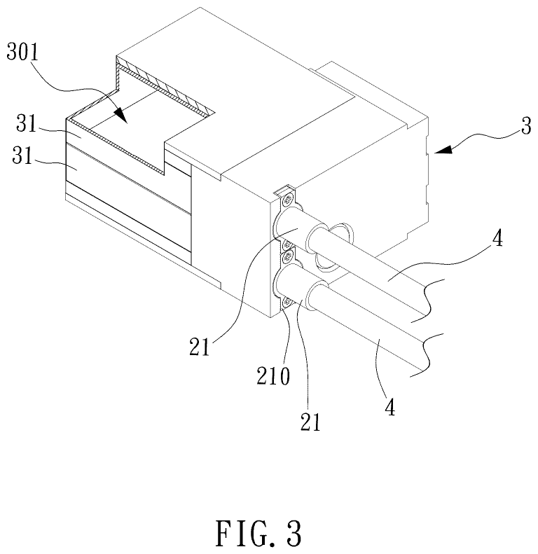

Please refer to FIGS. 1, 2 and 3, which show the perspective view, the exploded perspective view and the assembled perspective view of the water-cooling device connection structure. As illustrated, the water-cooling device connection structure includes a connection unit (2), a water-cooling unit (3), and at least one pipe (4). The pipe (4) is connected to the water-cooling unit (3) through the connection unit (2).

In the embodiment, the connection unit (2) is described as multiple connection units (2). Each connection unit (2) has at least one coupling component (20) and at least one mating component (21). In the embodiment, there are multiple coupling components (20) and mating components (21). One coupling component (20) pairs with one mating component (21) to form a connection unit (2). The number of coupling components (20) and mating components (21) may be adjusted based on the number of inlets (32) and outlets (33) on the water-cooling unit (3) to which they are attached. The coupling component (20) has a fixed base portion (200). The fixed base portion (200) is arranged with an extended portion (205) and multiple first flanges (201). The extended portion (205) is extended outwardly from the front of the fixed base portion (200). The extended portion (205) contains a first channel (207) with openings at both ends. The front opening (2081) is located at the front end of the extended portion (205), while the rear opening (2082) is at the rear end and passes through the rear side of the fixed base portion (200) which makes the first channel (207) to be located between the front opening (2081) and rear opening (2082) of the extended portion (205) and they are connected to each other.

The external side of the extended portion (205) is fitted with at least one leakage proofing portion (206). The leakage proofing portion (206) may be made from leak-proof material such as silicone, rubber, or other polymer materials (like Teflon). In the embodiment, multiple leakage proofing portions (206) are arranged as rings protruded around the external side of the extended portion (205) to prevent fluid leakage and to form a tight seal. The multiple first flanges (201) are extended outwardly from two external sides of the fixed base portion (200) that are opposite to each other. The multiple first flange (201) has a first through-hole (202) that penetrates from the front side to the rear side of the first flange (201).

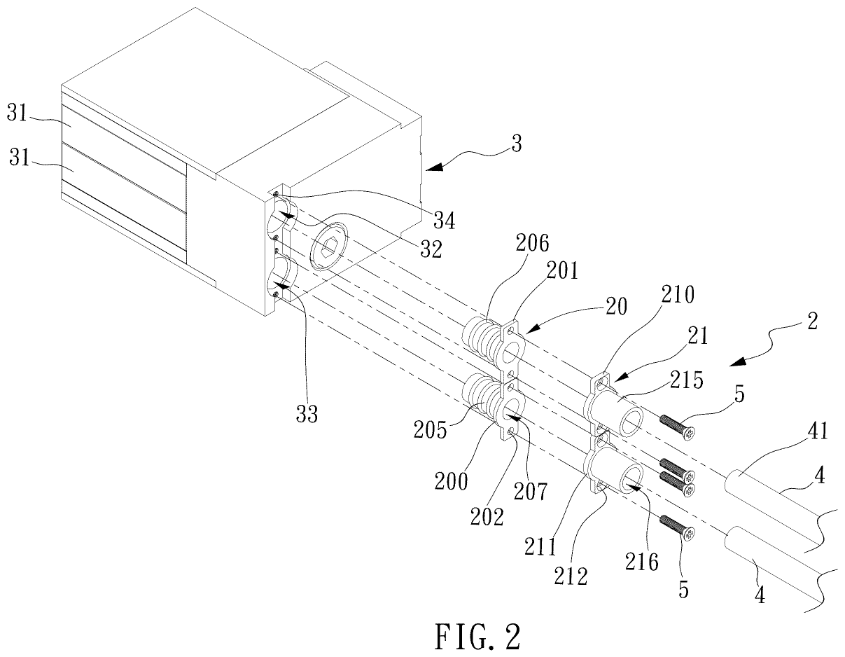

Referring to FIGS. 1 and 2 again, the mating component (21) has a receiving base portion (211) with a fitting portion (215) and multiple second flanges (210). The fitting portion (215) is extended outwardly from the rear side of the receiving base portion (211). A second channel (216) with openings at both ends is located inside the fitting portion (215). One front opening (2171) is at the front end of the fitting portion (215), passing through the front side of the receiving base portion (211), while the rear opening (2172) is at the rear end of the receiving base portion (211). The second channel (216) is located between the front opening (2171) and rear opening (2172) of the fitting portion (215), and they are connected to each other. The second channel (216) widens from the front opening (2171) to the rear opening (2172), forming a conical shape. The front opening (2171) of the second channel (216) connects with the rear opening (2082) of the first channel (207). The front side of the receiving base portion (211) is connected to the rear side of the fixed base portion (200) to form the said connection unit (2). The receiving base portion (211) may connect with the fixed base portion (200) through screws or snaps. This setup allows the coupling component (20) and mating component (21) to be repeatedly assembled and disassembled for reuse.

Each second flange (210) of the receiving base portion (211) has a second through-hole (212). The second through-hole (212) penetrates from the front side to the rear side of the second flange (210). Multiple fasteners (5), such as screws, rivets, or pins, pass through the second through-holes (212) of the second flanges (210) of the mating component (21) and the first through-holes (202) of the first flanges (201) of the coupling component (20) to secure them together. In the embodiment, pipe (4) is described as multiple pipes (4) (such as two pipes) that are paired with two corresponding connection units (2). Each pipe (4) has a connecting end (41) that is inserted into the rear opening (2172) of the fitting portion (215) of each connection unit (2). The connecting end (41) of the pipe (4) passes through the conical second channel (216), the rear opening (2082) of the coupling component (20), and the first channel (207) to connect at the position of the front opening (2081) adjacent to the coupling component (20). By making the diameter of the front opening (2171) of the conical second channel (216) smaller than the outer diameter of the pipe (4), the pipe (4) can be tightly and securely fitted into the fitting portion (215) of the mating component (21) without slipping off and effectively preventing the leakage of the working fluid. Additionally, an adhesive (such as glue or sealant) is applied on the contact surfaces of the pipe (4) and the fitting portion (215) of the mating component (21). The adhesive is coated on the outside of the connecting end (41) of the pipe (4) and adheres to the inner side of the fitting portion (215) of the mating component (21), thereby enhancing the bonding strength between the pipe (4) and the fitting portion (215) and improving leak-proof performance.

The materials for the coupling component (20), mating component (21), and fasteners (5) may be selected from metals, non-metals, plastics, or other polymers.

The water-cooling unit (3) has at least one pump (31), an inlet (32), and an outlet (33). In the embodiment, the at least one pump (31) is described as two pumps (31) that are stacked in series. Each pump contains a liquid-filled chamber (301) that connects the inlet (32) and outlet (33). The inlet (32) and outlet (33) are respectively located on one side of the water-cooling unit (3) and respectively connected to the coupling components (20) of two connection units (2). Specifically, the leakage proofing portions (206) on the extended portion (205) of the connection unit (2) are inserted into the inlet (32) and outlet (33) of the water-cooling unit (3) and form a tight seal, thereby allowing the working fluid inside the pipe (4) to flow into the chamber (301) of each pump (31) through the inlet (32). The driver of the pumps (not shown in the figures) drives the working fluid in each chamber (301) to flow toward and exit the outlet (33). Finally, the pipe (4) that is connected to the outlet (33) transports the working fluid to another water-cooling unit (e.g., a radiator, which is not shown in the figures) and circulates for continuous cooling. Additionally, several locking holes (34) may be arranged around the inlet (32) and outlet (33) of the water-cooling unit (3). The connection units (2) are secured to the corresponding locking holes (34) of the water-cooling unit (3) with the fasteners (5), which, in this embodiment are screws. This enhances the bonding strength between the connection unit (2) and the water-cooling unit (3).

In alternative embodiments, the water-cooling unit (3) may include a single pump, a water block, or other water-cooling components (e.g., a radiator) instead of and not limited to the multiple pumps (31) described in the embodiment described previously.

Through the design of the present invention, the pipe (4) passes through the second channel (216) of the mating component (21) and fits into the first channel (207) of the extended portion (205) of the coupling component (20), allowing the mating component (21) and the coupling component (20) to connect with each other. The fixed base portion (200) of the coupling component (20) is inserted and installed within the water-cooling unit (3), securing the pipe (4) to the water-cooling unit (3) via the connection unit (2). This design thereby improves the shortcomings of the pipe being fixed to the water-cooling unit through welding, which is prone to issues of working fluid leakage.

Moreover, the coupling component (20) and mating component (21) are easy to manufacture, can be repeatedly assembled and disassembled, and contribute to reduced production costs.

Compared to conventional designs, the present invention has the following advantages:
1. Significantly reduces fluid leakage issues.
2. Simple manufacturing process.
3. Reusable components that greatly reduce production costs.

This detailed description outlines the preferred embodiment of the invention, but it is not intended to limit the invention's scope. Any equivalent variations or modifications based on the claims are considered within the scope of this patent.

What is claimed is:

1. A water-cooling device connection structure, comprising:
a water-cooling unit, having an inlet, an outlet, and a chamber connecting the inlet and the outlet;
at least one connection unit, having a coupling component and a mating component, the coupling component having a fixed base portion with an extended portion extending outwardly from the front of the fixed base portion, the extended portion containing a first channel, the external side of the extended portion fitted with at least one leakage proofing portion, the extended portion connecting to the inlet or outlet of the water-cooling unit through the leakage proofing portion,
the mating component having a receiving base portion, the front of the receiving base portion connecting to the rear of the coupling component, the rear of the receiving base portion extended outwardly with a fitting portion, the fitting portion containing a second channel, and the second channel connecting to the first channel; and
at least one pipe, having a connecting end, the connecting end fitted into the second channel of the mating component and combined within the first channel of the coupling component, thereby connecting the chamber of the water-cooling unit with the pipe.

2. The water-cooling device connection structure as claimed in claim 1, wherein the fixed base portion has multiple first flanges that are extended outwardly from two external sides of the fixed base portion that are opposite to each other, each first flange includes a first through-hole that penetrates from the front to the back of the first flange.

3. The water-cooling device connection structure as claimed in claim 2, wherein the receiving base portion has multiple second flanges, each with a second through-hole, the second through-hole penetrates from the front to the back of the second flange, multiple fasteners pass through the second through-holes of the second flanges and into the first through-holes of the first flanges to secure the second flanges and the first flanges.

4. The water-cooling device connection structure as claimed in claim 1, wherein the extended portion of the coupling component is tightly fitted into the water-cooling unit via the leakage proofing portion.

5. The water-cooling device connection structure as claimed in claim 1, wherein the connecting end of the pipe and the fitting portion of the mating component are bonded together using an adhesive.

6. The water-cooling device connection structure as claimed in claim 1, wherein the inner diameter of the second channel gradually increases from the front opening to the rear opening of the fitting portion, forming a conical channel.
